(19) United States
(12) Patent Application Publication
(10) Pub. No.: US 2025/0147067 A1
(43) Pub. Date: May 8, 2025

(54) PROBE SYSTEM FOR DOUBLE SIDE PROBING, METHOD OF OPERATING THE SAME AND TESTED DEVICE

(71) Applicant: MPI CORPORATION, CHU-PEI CITY (TW)

(72) Inventors: PO-YI TING, CHU-PEI CITY (TW); YU-HSUN HSU, CHU-PEI CITY (TW); TING-AN YEN, CHU-PEI CITY (TW); SEBASTIAN GIESSMANN, CHU-PEI CITY (TW)

(73) Assignee: MPI CORPORATION, CHU-PEI CITY (TW)

(21) Appl. No.: 18/938,623

(22) Filed: Nov. 6, 2024

Related U.S. Application Data
(60) Provisional application No. 63/547,685, filed on Nov. 7, 2023.

(51) Int. Cl. G01R 1/04; G01R 31/28; G01R 31/308

(52) U.S. Cl. CPC G01R 1/0491; G01R 31/2831; G01R 31/308

(57) ABSTRACT

A probe system for double side probing includes a chuck having a through hole for a substrate including a DUT to be disposed on the chuck and defined with an edge part supported by the chuck and a central part located correspondingly to the through hole, upper and lower probe devices, including electrical and optical probe devices, disposed above and below the through hole respectively for testing the DUT on top and bottom sides of the substrate, and a support device disposed on the side of the chuck opposite to the electrical probe device. When an electrical probe of the electrical probe device contacts the top or bottom side of the substrate, a supporter of the support device contacts the other side and is located adjacent to the electrical probe with the substrate located therebetween to resist the force from the electrical probe to avoid substrate deformation.

### BACKGROUND OF THE INVENTION

### 1. Field of the Invention

The present invention relates generally to probe systems for testing electronic components such as semiconductor dies and more particularly, to a probe system for double side probing, a method of operating the probe system, and a tested device.

### 2. Description of the Related Art

Probe systems may be utilized to probe and/or to test the operation of a device under test (also referred to as DUT hereinafter). In the electronics industry, probe systems historically have taken the form of electrical probe systems that provide a probe electric current to the DUT and/or that receive a corresponding resultant electric current from the DUT. More recently, optical probe systems have been developed to probe optical DUTs that include optical components. Conventionally, both electrical probe systems and optical probe systems (e.g. optical fibers) have conveyed test signals to the DUT and/or received resultant signals from the DUT from, or from above, a substrate surface of a substrate that includes the DUT. As an example, a probe system may utilize a silicon photonics coupling technique in which one or more optical fibers interface with the DUT via an optical signal. In such an example, each optical fiber generally does not contact the DUT, but instead is aligned with an optical coupler on the DUT, such as a grating coupler, to transmit and receive the optical signal.

Referring to FIG. 1, the conventional probe system 10 for double side probing primarily includes a chuck 11, an electrical probe device 12, and an optical probe device 13. The chuck 11 has a through hole 111 so that when a wafer 14 is placed on the chuck 11, the chuck 11 only supports the edge of the wafer 14. In this way, the top side 151 and the bottom side 152 of the dies 15 included in the wafer 14 can be probed by the electrical probe device 12 and the optical probe device 13 respectively. Specifically speaking, this probing process is performed when the wafer 14 has been manufactured with a large number of dies 15 connected with each other, which means at this time the wafer 14 has not been diced into a large number of separate dies 15 yet. For the simplification of the figure and the convenience of illustration, only one die 15 is schematically shown in FIG. 1, and this die 15 is drawn relatively larger. In practice, the wafer 14 includes a large number of dies 15, and they have a tiny size. The top side 151 of the die 15 includes a plurality of conductive pads (not shown). The electrical probe device 12 is disposed above the chuck 11 for contacting the conductive pads of the die 15 by electrical probes 121 thereof, so as to perform an electrical test to the die 15. The bottom side 152 of the die 15 includes a plurality of optical receiving portions and/or optical transmitting portions (not shown). The optical probe device 13 is disposed below the chuck 11 for emitting light to and/or receiving light from the optical receiving portions and/or optical transmitting portions of the die 15, so as to perform an optical test to the die 15. Alternatively, the conductive pads of the die 15 may be located on the bottom side 152, and the optical receiving portions and/or optical transmitting portions are located on the top side 151. In such condition, the electrical probe device 12 and the optical probe device 13 are disposed below and above the chuck 11 respectively.

Take the condition that the electrical probe device 12 is disposed above the chuck 11 as an example, as shown in FIG. 1. Because the chuck 11 only supports the edge of the wafer 14, when the top side 151 of the die 15 is contacted by the electrical probes 121 of the electrical probe device 12, the wafer 14 will be slightly deformed in a downward bent manner, as shown with the imaginary lines in FIG. 1. On the contrary, if the bottom side 152 of the die 15 is contacted by the electrical probes 121 of the electrical probe device 12, the wafer 14 will be slightly deformed in an upward bent manner. Since such arrangement benefits from accurate alignment between the optical fiber (not shown) of the optical probe device 13 and the optical coupler (not shown) of the DUT so that power transmission between the optical fiber and the DUT is enhanced, the aforesaid deformation of the wafer 14 may cause unfavorable affection to the performance of the die 15 or the accuracy of the test result thereof.

### SUMMARY OF THE INVENTION

The present invention has been accomplished in view of the above-noted circumstances. It is an objective of the present invention to provide a probe system for double side probing, which is effective in preventing a substrate including a DUT from deformation when the DUT is contacted by an electrical probe device, so as to avoid the problem caused by the substrate deformation that the optical probe device and the DUT cannot be accurately aligned with each other to result in low accuracy to the test result.

To attain the above objective, the present invention provides a probe system for double side probing, which is configured for testing one or more DUTs of a substrate (e.g. wafer). The probe system includes a chuck, an upper probe device, a lower probe device, and a support device which includes a supporter. The chuck is configured to support the substrate. The chuck includes a through hole for the substrate to be disposed on the chuck in a way that the substrate is defined with a central part located correspondingly to the through hole and an edge part located around the central part and supported by the chuck. The upper probe device is disposed above the through hole of the chuck for testing the DUT on a top side of the substrate. The lower probe device is disposed below the through hole of the chuck for testing the DUT on a bottom side of the substrate. The bottom side and the top side of the substrate are opposite to each other, and the bottom side faces toward the chuck. One of the upper and lower probe devices is an electrical probe device. The electrical probe device includes an electrical probe. The other of the upper and lower probe devices is an optical probe device. The optical probe device includes a fiber optical transceiver. The optical probe device and the support device are individually movable relative to the chuck. One of the support device and the electrical probe device is disposed above the through hole of the chuck. The other of the support device and the electrical probe device is disposed below the through hole of the chuck. When the DUT is tested by the electrical probe device, the electrical probe is in contact with one of the top and bottom sides of the substrate, and the supporter of the support device is in contact with the other of the top and bottom sides of the substrate and located adjacent to the electrical probe with the substrate located therebetween.

As a result, the above-described probe system may be arranged in a way that the electrical probe device is located above the chuck, which means the upper probe device is the electrical probe device, the support device is located below the chuck, and the optical probe device is also located below the chuck, which means the lower probe device is the optical probe device. In this way, the upper and lower probe devices can test the DUT at the same time, thereby attaining the double side probing function. Besides, when the electrical probe of the electrical probe device applies a downward force on the top surface of the substrate, the supporter of the support device can be in contact with the bottom side of the substrate at a position adjacent to where the substrate is applied with the downward force, so as to resist the force from the electrical probe, thereby effectively preventing the substrate from deformation. Alternatively, the above-described probe system may be arranged in the other way that the electrical probe device is located below the chuck, which means the lower probe device is the electrical probe device, the support device is located above the chuck, and the optical probe device is also located above the chuck, which means the upper probe device is the optical probe device. In this way, the upper and lower probe devices can test the DUT at the same time, thereby attaining the double side probing function. Besides, when the electrical probe of the electrical probe device applies an upward force on the bottom surface of the substrate, the supporter of the support device can be in contact with the top side of the substrate at a position adjacent to where the substrate is applied with the upward force, so as to resist the force from the electrical probe, thereby effectively preventing the substrate from deformation. Because the support device and the optical probe device are individually movable relative to the chuck, the support device and the optical probe device can be located at their respective required positions accurately. The support device can be moved relative to the chuck to locate the supporter adjacent to where the substrate receives the force from the electrical probe, which means the supporter is located adjacent to the electrical probe with the substrate located therebetween, so that great support effect is attained and thereby the substrate is effectively prevented from deformation during being contacted by the electrical probe device. Besides, the optical probe device utilizes the fiber optical transceiver which can be accurately aligned with the DUT and thereby attains great optical probing effect, and the above-described effect of preventing the substrate from deformation can further effectively avoid the problem caused by the substrate deformation that the optical probe device and the DUT cannot be accurately aligned with each other to result in low accuracy to the test result.

In an embodiment of the present invention, the lower probe device is the electrical probe device for performing an electrical test to the DUT by contacting the bottom side of the substrate by the electrical probe. The support device is disposed above the through hole of the chuck for contacting the top side of the substrate by the supporter. The upper probe device is the optical probe device for performing an optical test to the DUT on the top side of the substrate.

As a result, the above-described probe system is adapted for the DUT requiring the electrical test on the bottom side and requiring the optical test on the top side, and during the testing process, the supporter of the support device can be utilized on the top side of the substrate to resist the upward force applied to the substrate by the electrical probe, so as to effectively prevent the substrate from deformation.

In another embodiment of the present invention, the upper probe device is the electrical probe device for performing an electrical test to the DUT by contacting the top side of the substrate by the electrical probe. The support device is disposed below the through hole of the chuck for contacting the bottom side of the substrate by the supporter. The lower probe device is the optical probe device for performing an optical test to the DUT on the bottom side of the substrate.

As a result, the above-described probe system is adapted for the DUT requiring the electrical test on the top side and requiring the optical test on the bottom side, and during the testing process, the supporter of the support device can be utilized on the bottom side of the substrate to resist the downward force applied to the substrate by the electrical probe, so as to effectively prevent the substrate from deformation.

Preferably, the support device further includes a heater. The heater is configured to control the temperature of the supporter when the DUT is tested by the upper probe device and the lower probe device, so as to heat the DUT through thermal conduction when the supporter is in contact with the substrate.

As a result, the above-described probe system is adapted for the DUT required to be tested under high-temperature condition. The DUT can be heated to the temperature required for the test. Besides, the position where the supporter contacts the substrate can be adjacent to the DUT in the testing process, such that great support effect can be attained, and the DUT in the testing process can be efficiently heated and maintained in temperature.

Preferably, the above-described probe system further includes a non-contact heating device. The non-contact heating device is configured to heat the DUT via thermal radiation when the DUT is tested by the upper probe device and the lower probe device.

As a result, the above-described probe system can utilize the support device to heat the DUT, and at the same time also utilize the non-contact heating device to heat the DUT, thereby attaining relatively higher heating efficiency. Alternatively, the above-described probe system can utilize only the non-contact heating device to heat the DUT, which means the support device may include no heater, such that the support device is relatively simpler in structure.

Preferably, when the DUT is tested by the electrical probe device, the distance defined on a horizontal axis between the position where the substrate is contacted by the supporter and the position where the substrate is contacted by the electrical probe is smaller than the length of the DUT defined on the horizontal axis, so that the supporter is located adjacent to the electrical probe and thereby attains great support effect, so as to effectively prevent the substrate from deformation when the substrate is contacted by the electrical probe.

Preferably, the optical probe device includes a distance sensor for measuring the distance between the optical probe device and the substrate to generate a distance value for a determination of whether the supporter of the support device is in contact with the substrate by the variation of the distance value.

As a result, the distance sensor of the optical probe device can be utilized to not only ensure that the distance between the optical probe device and the substrate is adapted for the optical test, but also determine whether the supporter of the support device is in contact with the substrate by the variation of the distance obtained by the distance sensor so as to ensure that the supporter can effectively resist the force from the electrical probe to prevent the substrate from deformation.

The present invention further provides a method of operating the above-described probe system which can determine whether the supporter of the support device is in contact with the substrate. The method includes the steps of:
disposing the substrate on the chuck;
moving the optical probe device and the chuck relative to each other to position the optical probe device adjacent to the DUT of the substrate;
using the distance sensor of the optical probe device to measure the distance between the optical probe device and the substrate to generate the distance value, moving the support device relative to the chuck to bring the supporter to be in contact with the substrate, and determining that the supporter of the support device is in contact with the substrate when the distance value obtained by the distance sensor of the optical probe device has a variation; and
under the status that the supporter of the support device is in contact with the substrate, performing an electrical test to the DUT by bringing the electrical probe of the electrical probe device into contact with the DUT, and performing an optical test to the DUT by the optical probe device.

As a result, the distance sensor of the optical probe device can be utilized to not only ensure that the distance between the optical probe device and the substrate is adapted for the optical test, but also determine whether the supporter of the support device is in contact with the substrate by the variation of the distance obtained by the distance sensor so as to ensure that the DUT is tested under the status that the supporter is in contact with the substrate so that the supporter can resist the force from the electrical probe during the testing process, thereby effectively preventing the substrate from deformation.

The present invention further provides a method of operating the above-described probe system which utilizes the supporter of the support device to resist the force from the electrical probe. The method includes disposing the substrate on the chuck, and under the status that the supporter of the support device is in contact with the substrate, testing the DUT by the upper probe device on the top side of the substrate, and testing the DUT by the lower probe device on the bottom side of the substrate. The upper probe device, the lower probe device and the support device are arranged in a way that the lower probe device is the electrical probe device and performs an electrical test to the DUT by contacting the bottom side of the substrate by the electrical probe, the support device is disposed above the through hole of the chuck and contacts the top side of the substrate by the supporter, and the upper probe device is the optical probe device and performs an optical test to the DUT on the top side of the substrate. Alternatively, the upper probe device, the lower probe device and the support device are arranged in a way that the upper probe device is the electrical probe device and performs an electrical test to the DUT by contacting the top side of the substrate by the electrical probe, the support device is disposed below the through hole of the chuck and contacts the bottom side of the substrate by the supporter, and the lower probe device is the optical probe device and performs an optical test to the DUT on the bottom side of the substrate.

As a result, the above-described method is adapted for the DUT requiring the electrical test on the bottom side and requiring the optical test on the top side, or the DUT requiring the electrical test on the top side and requiring the optical test on the bottom side, and can use the supporter of the support device to resist the force applied to the substrate by the electrical probe during the testing process, so as to effectively prevent the substrate from deformation.

Preferably, in the above-described method, the fiber optical transceiver of the optical probe device includes an optical transceiving surface. The optical probe device, when performing the optical test to the DUT, is arranged in a way that the optical transceiving surface of the fiber optical transceiver faces toward a top surface of the top side of the substrate to perform the optical test to the DUT. Alternatively, the optical probe device, when performing the optical test to the DUT, is arranged in a way that the fiber optical transceiver is inserted into a recess of the top side of the substrate, and the optical transceiving surface faces toward an inner side wall of the recess to perform the optical test to the DUT. Alternatively, the optical probe device, when performing the optical test to the DUT, is arranged in a way that the optical transceiving surface of the fiber optical transceiver faces toward a bottom surface of the bottom side of the substrate to perform the optical test to the DUT. Alternatively, the optical probe device, when performing the optical test to the DUT, is arranged in a way that the fiber optical transceiver is inserted into a recess of the bottom side of the substrate, and the optical transceiving surface faces toward an inner side wall of the recess to perform the optical test to the DUT.

As a result, the above-described method utilizing the fiber optical transceiver can effectively emit light to the DUT and receive light from the DUT, so as to attain great optical probing effect. Besides, in the condition that the substrate requires the optical test on the top side, the optical receiving portions and optical transmitting portions of the DUT can be located on the top surface of the substrate, and the optical transceiving surface of the fiber optical transceiver can be configured to face toward the top surface of the substrate to perform the optical test to the DUT. Alternatively, the optical receiving portions and optical transmitting portions of the DUT can be located on the inner side wall of the recess of the top side of the substrate, and the optical transceiving surface of the fiber optical transceiver can be configured to face toward the inner side wall of the recess to perform the optical test to the DUT. Similarly, in the condition that the substrate requires the optical test on the bottom side, the optical receiving portions and optical transmitting portions of the DUT can be located on the bottom surface of the substrate, and the optical transceiving surface of the fiber optical transceiver can be configured to face toward the bottom surface of the substrate to perform the optical test to the DUT. Alternatively, the optical receiving portions and optical transmitting portions of the DUT can be located on the inner side wall of the recess of the bottom side of the substrate, and the optical transceiving surface of the fiber optical transceiver can be configured to face toward the inner side wall of the recess to perform the optical test to the DUT.

To attain the above objective, the present invention further provides another probe system for double side probing, which is configured for testing one or more DUTs of a substrate. The probe system includes a chuck, an upper probe device, and a lower probe device. The chuck includes a supporting part which is grid-shaped. The supporting part includes an upper surface, a lower surface, and a plurality of through holes penetrating through the upper surface and the lower surface for the substrate to be disposed on the upper surface of the supporting part in a way that the substrate is partially located correspondingly to every through hole. The upper probe device is disposed above the supporting part of the chuck and realized as an electrical probe device. The electrical probe device includes an electrical probe for testing the DUT by contacting a top side of the substrate by the electrical probe. The lower probe device is disposed below the supporting part of the chuck and realized as an optical probe device. The optical probe device includes a fiber optical transceiver for testing the DUT on a bottom side of the substrate through the through hole of the supporting part.

As a result, the supporting part of the chuck supports the bottom side of the substrate. Besides, the supporting part is grid-shaped, that can not only support the substrate effectively, but also has the through holes to expose the bottom side of the substrate partially for the lower probe device to test the DUT on the bottom side of the substrate. In other words, the upper and lower probe devices can test the DUT at the same time, thereby attaining the double side probing function. Besides, when the electrical probe of the electrical probe device applies a downward force on the top surface of the substrate, the supporting part which supports the bottom side of the substrate can resist the force from the electrical probe, so as to effectively prevent the substrate from deformation. In addition, the optical probe device utilizes the fiber optical transceiver which can be accurately aligned with the DUT and thereby attains great optical probing effect, and the above-described effect of preventing the substrate from deformation can further effectively avoid the problem caused by the substrate deformation that the optical probe device and the DUT cannot be accurately aligned with each other to result in low accuracy to the test result.

Preferably, the chuck further includes a heater adapted for heating the substrate through thermal conduction when the supporting part is in contact with the substrate.

As a result, the above-described probe system is adapted for the DUT required to be tested under high-temperature condition. The DUT can be heated to the temperature required for the test. Besides, the supporting part of the chuck is in contact with the bottom side of the substrate, that can not only attain great support effect, but also efficiently heat the DUT and maintain its temperature.

More preferably, the heater is disposed in the supporting part.

As a result, the supporting part of the chuck is in contact with the bottom side of the substrate, so the heater disposed in the supporting part can heat the DUT and maintain its temperature relatively more efficiently.

The present invention further provides a method of operating the above-described probe system which uses the supporting part of the chuck to resist the force from the electrical probe. The method includes disposing the substrate on the upper surface of the supporting part of the chuck, testing the DUT by the upper probe device on the top side of the substrate, and testing the DUT by the lower probe device on the bottom side of the substrate, wherein the upper probe device is the electrical probe device and performs an electrical test to the DUT by contacting the top side of the substrate by the electrical probe, the lower probe device is the optical probe device, and the fiber optical transceiver faces toward the bottom side of the substrate to perform an optical test to the DUT.

As a result, the above-described method is adapted for the DUT requiring the electrical test on the top side and requiring the optical test on the bottom side, and during the testing process, the supporting part of the chuck which supports the bottom side of the substrate can resist the downward force applied to the top side of the substrate by the electrical probe, so as to effectively prevent the substrate from deformation.

Preferably, in the above-described method, the fiber optical transceiver of the optical probe device includes an optical transceiving surface. The optical probe device, when performing the optical test to the DUT, is arranged in a way that the optical transceiving surface of the fiber optical transceiver faces toward a bottom surface of the bottom side of the substrate to perform the optical test to the DUT. Alternatively, the optical probe device, when performing the optical test to the DUT, is arranged in a way that the fiber optical transceiver is inserted into a recess of the bottom side of the substrate, and the optical transceiving surface faces toward an inner side wall of the recess to perform the optical test to the DUT.

As a result, the above-described method using the fiber optical transceiver can effectively emit light to the DUT and receive light from the DUT, so as to attain great optical probing effect. Besides, the optical receiving portions and optical transmitting portions of the DUT can be located on the bottom surface of the substrate, and the optical transceiving surface of the fiber optical transceiver can be configured to face toward the bottom surface of the substrate to perform the optical test to the DUT. Alternatively, the optical receiving portions and optical transmitting portions of the DUT can be located on the inner side wall of the recess of the bottom side of the substrate, and the optical transceiving surface of the fiber optical transceiver can be configured to face toward the inner side wall of the recess to perform the optical test to the DUT.

The present invention further provides a tested device which has been tested through a testing process. The testing process is performed by using anyone of the above-described methods of operating a probe system for double side probing.

As a result, the above-described methods of operating the probe system can effectively prevent the substrate from deformation, so that the performance of the tested device and/or the accuracy of the test result thereof is prevented from unfavorable affection caused by substrate deformation.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic sectional view of a conventional probe system for double side probing and a wafer.

FIG. 2 is a schematic sectional view of a probe system for double side probing and a substrate according to a first preferred embodiment of the present invention.

FIG. 3 is a schematic sectional view of a probe system for double side probing and a substrate according to a second preferred embodiment of the present invention.

FIG. 4 and FIG. 5 are partial schematic sectional views showing two other types of arrangement of the substrate and a fiber optical transceiver.

FIG. 6 is a schematic sectional view of a probe system for double side probing and a substrate according to a third preferred embodiment of the present invention.

FIG. 7 is a schematic bottom view of a chuck of the probe system and the substrate according to the third preferred embodiment of the present invention.

FIG. 8 is similar to FIG. 6, but showing another type of chuck.

FIG. 9 is a flow chart of a method of operating the probe system for double side probing according to the first preferred embodiment of the present invention.

FIG. 10 is a flow chart of another method of operating the probe system.

FIG. 11 is a flow chart of a method of operating the probe system for double side probing according to the third preferred embodiment of the present invention.

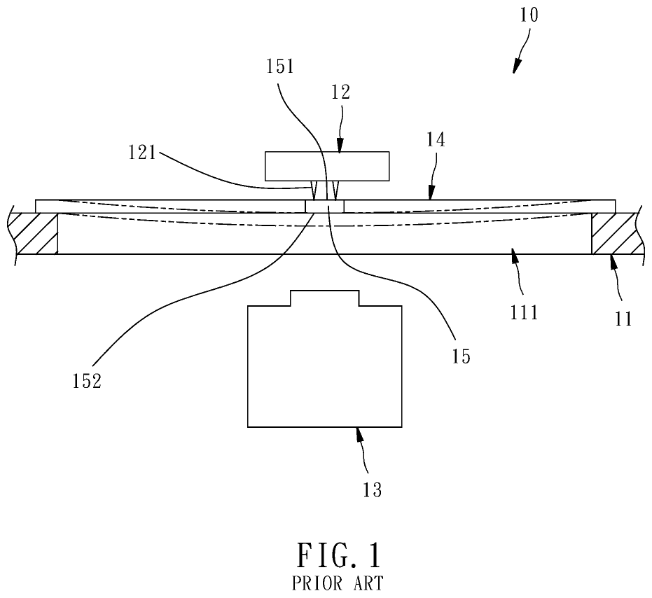

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

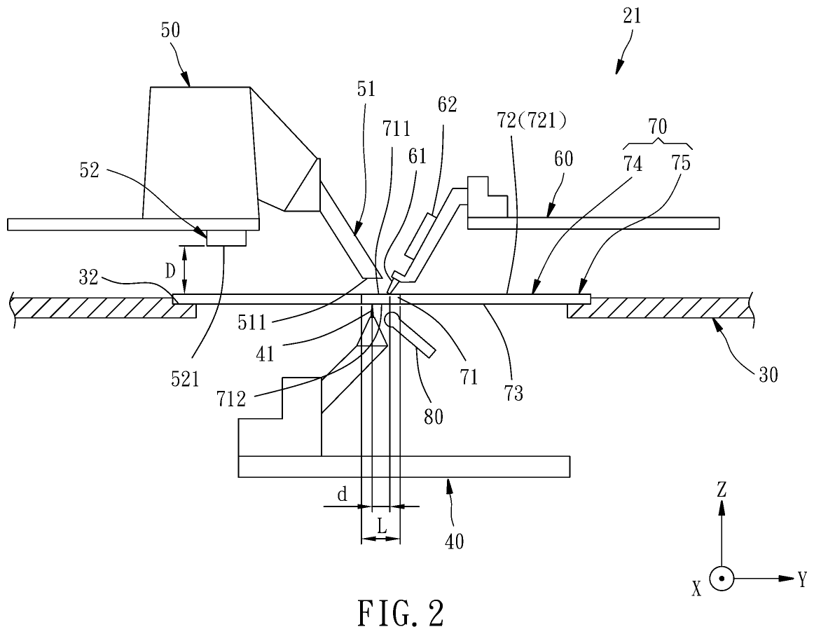

Referring to FIG. 2, a probe system 21 for double side probing according to a first preferred embodiment of the present invention primarily includes a chuck 30, an electrical probe device 40, an optical probe device 50, and a support device 60. In this embodiment, the electrical probe device 40 is a lower probe device, and the optical probe device 50 is an upper probe device.

The probe system of the present invention is configured for testing one or more DUTs 71 of a substrate 70 (e.g. wafer). For the simplification of the figures and the convenience of illustration, only one DUT 71 is schematically shown in the figures, and this DUT 71 is drawn relatively larger. In practice, the substrate 70 includes a large number of DUTs 71, and they have a tiny size. The substrate 70 includes a top side 72 and a bottom side 73 opposite to each other. The DUT 71 also correspondingly has a top side 711 and a bottom side 712. The top side 711 and bottom side 712 of the DUT 71 are parts of the top side 72 and bottom side 73 of the substrate 70 respectively. In this embodiment, the bottom side 712 of the DUT 71 includes a plurality of conductive pads (not shown), and the top side 711 of the DUT 71 includes a plurality of optical receiving portions and/or optical transmitting portions (not shown). In other words, the DUT 71 in this embodiment requires an electrical test on the bottom side 712, and requires an optical test on the top side 711.

The chuck 30 is configured to support the substrate 70 for the substrate 70 to be disposed on the chuck 30 in a way that the bottom side 73 faces toward the chuck 30. In some embodiments and as schematically illustrated in FIG. 2, the chuck 30 is configured to contact the substrate 70 only along a peripheral region of the substrate 70. Specifically speaking, the chuck 30 includes a through hole 31. When the substrate 70 is disposed on the chuck 30, the substrate 70 is defined with a central part 74 located correspondingly to the through hole 31, and an edge part 75 located around the central part 74 and supported by the chuck 30. The above-described peripheral region of the substrate 70 contacted by the chuck 30 is the edge part 75. As used herein and as schematically illustrated in FIG. 2, the edge part 75 of the substrate 70 may refer to any suitable region of the substrate 70, such as any suitable region of the top side of the substrate and/or of the bottom side of the substrate, which at least partially bounds, surrounds, encloses, and/or encompasses a central region of substrate 70 (i.e. the above-described central part 74) that is accessible to and/or that is tested by the upper and lower probe devices (i.e. the optical probe device 50 and the electrical probe device 40) and the support device 60. More specifically, in some embodiment and as schematically illustrated in FIG. 2, the chuck 30 includes a support surface 32 that is configured to contact the bottom side 73 of the substrate 70 along the edge part 75 of the substrate 70. The support surface 32 of the chuck 30 may support the edge part 75 of the substrate 70 along a full perimeter of the substrate 70, or may support the edge part 75 along a region of the substrate 70, and/or along a plurality of spaced-apart regions of the substrate 70.

The upper probe device in this embodiment is the optical probe device 50, which is disposed above the through hole 31 of the chuck 30 for testing the DUT 71 on the top side 72 of the substrate 70. Specifically speaking, the optical probe device 50 is movable relative to the chuck 30, which means one or both of the optical probe device 50 and the chuck 30 can be moved to change their relative position. The optical probe device 50 includes a fiber optical transceiver 51. The fiber optical transceiver 51 includes an optical transceiving surface 511 which can be accurately aligned with the optical receiving portions and/or optical transmitting portions of the top side 711 of the DUT 71, so as to effectively emit light to the DUT 71 and receive light from the DUT 71, thereby attaining great optical probing effect. The probe system 21 may include a signal generation and analysis assembly (not shown). The signal generation and analysis assembly, when present, may be adapted, configured, designed, and/or constructed to provide a test signal to the DUT 71 via an optical probe tip (e.g. optical transceiving surface 511) of the optical probe device 50 and/or receive a resultant signal from the DUT 71 via the optical probe tip. Examples of the test signal include an optical test signal. Examples of the resultant signal include an optical resultant signal. Examples of the signal generation and analysis assembly include a signal generator, an electric signal generator, an optical signal generator, a signal transmitter, an electric signal transmitter, an optical signal transmitter, a signal receiver, an electric signal receiver, an optical signal receiver, a signal analyzer, an electric signal analyzer, and/or an optical signal analyzer. The optical probe device 50 may include any suitable structure which may include an optical probe, such as a fiber optical transceiver 51. For example, the optical probe device 50 and/or its optical probe may include and/or be an optical fiber cable. Examples of the optical fiber cable include a cleaved optical fiber cable, a lens optical fiber cable, a 3D printing optical fiber assembly, and/or a multi-surface optical fiber cable. The optical probe may be configured to transmit optical signal whose examples include infrared (IR) optical signal and/or visible spectrum optical signal.

The lower probe device in this embodiment is the electrical probe device 40, which is disposed below the through hole 31 of the chuck 30 for testing the DUT 71 on the bottom side 73 of the substrate 70. Specifically speaking, the electrical probe device 40 is movable relative to the chuck 30, which means one or both of the electrical probe device 40 and the chuck 30 can be moved to change their relative position. The electrical probe device 40 includes an electrical probe 41 (unlimited in amount) which can accurately contact the conductive pads of the bottom side 712 of the DUT 71, electrically connecting the DUT 71 and a tester (not shown) with each other through the electrical probe device 40 and thereby able to transmit electrical signal to each other, so that an electrical test can be performed to the DUT 71. The probe system 21 may include a signal generation and analysis assembly (not shown). The signal generation and analysis assembly, when present, may be adapted, configured, designed, and/or constructed to provide a test signal to the DUT 71 via a probe tip (e.g. the electrical probe 41) of the electrical probe device 40 and/or receive a resultant signal from the DUT 71 via the probe tip. Examples of the test signal include an electric test signal and/or an electromagnetic test signal. Examples of the resultant signal include an electric resultant signal and/or an electromagnetic resultant signal. Examples of the signal generation and analysis assembly include a signal generator, an electric signal generator, an optical signal generator, a signal transmitter, an electric signal transmitter, an optical signal transmitter, a signal receiver, an electric signal receiver, an optical signal receiver, a signal analyzer, an electric signal analyzer, and/or an optical signal analyzer.

In this embodiment, the electrical probe device 40 is disposed below the through hole 31 of the chuck 30, so the support device 60 is disposed above the through hole 31 of the chuck 30 for supporting the substrate 70. Specifically speaking, the support device 60 is movable relative to the chuck 30, which means one or both of the support device 60 and the chuck 30 can be moved to change their relative position. The support device 60 includes a supporter 61 which is shaped as a thin rod with a slightly tapered head and thereby can accurately contact the position of the substrate 70 requiring support. The supporter 61 may, but unlimited to, be made of soft material such as rubber, plastics, silicone, and so on. More specifically speaking, when the DUT 71 is tested by the electrical probe device 40, the electrical probe 41 is in contact with the bottom side 73 of the substrate 70, and the supporter 61 of the support device 60 is in contact with the top side 72 of the substrate 70 and located adjacent to the electrical probe 41 with the substrate 70 located therebetween. That means the supporter 61 may be located opposite to the electrical probe 41 with the substrate 70 located therebetween, or located as close to the position opposite to the electrical probe 41 as possible. Specifically speaking, the supporter 61 is arranged to be adjacent to the electrical probe device 40. Preferably, when the test is performed, the distance defined on a horizontal axis between the supporter 61 and the electrical probe 41 of the electrical probe device 40, such as the distance d defined on Y-axis, is smaller than the length L of a single DUT 71 defined on the horizontal axis. The supporter 61 of the support device 60 is configured to contact the substrate 70 and/or the DUT 71 in a point contact manner. The point contact manner usually refers to that the part of two objects in contact with each other is only a tiny point, not a surface or line, which emphasizes that the contact area is very small. In practice, the contact usually centralized in a very small area or point.

As a result, when the DUT 71 is tested by the probe system 21 in this embodiment, the optical probe device 50 and the electrical probe device 40 can test the DUT 71 on the top side 711 and the bottom side 712 at the same time, thereby attaining the double side probing function. Meanwhile, the electrical probe 41 of the electrical probe device 40 applies an upward force on the bottom side 73 of the substrate 70, and the supporter 61 of the support device 60 is in contact with the top side 72 of the substrate 70 at a position adjacent to where the substrate 70 is applied with the upward force, so as to resist the force from the electrical probe 41, thereby effectively preventing the substrate 70 from deformation. In this way, it can avoid the problem caused by the deformation of the substrate 70 that the optical probe device 50 and the DUT 71 cannot be accurately aligned with each other to result in low accuracy to the test result.

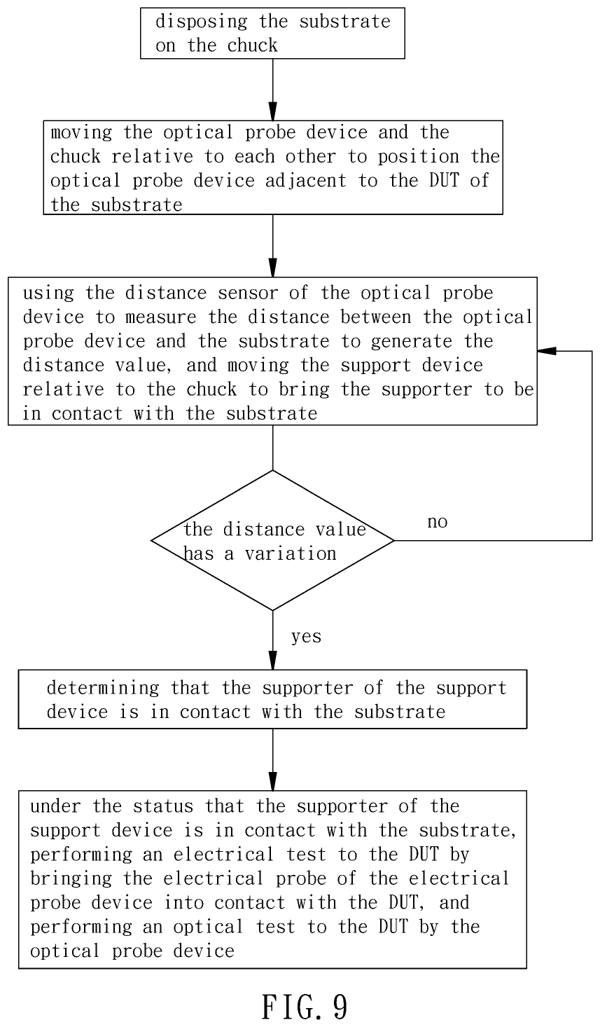

Further speaking, the probe system 21 in this embodiment can determine whether the supporter 61 of the support device 60 is in contact with the substrate 70 by using a distance sensor 52 included in the optical probe device 50, and the associated method of operating the probe system 21 includes the following steps a) to d), as shown in FIG. 9.
a) Dispose the substrate 70 on the chuck 30.
b) Move the optical probe device 50 and the chuck 30 relative to each other to position the optical probe device 50 adjacent to the DUT 71 of the substrate 70.
c) Use the distance sensor 52 of the optical probe device 50 to measure the distance D between the optical probe device 50 and the substrate 70 to generate a distance value, and move the support device 60 relative to the chuck 30 to bring the supporter 61 to be in contact with the substrate 70. When the distance value obtained by the distance sensor 52 of the optical probe device 50 has a variation, determine that the supporter 61 of the support device 60 is in contact with the substrate 70. In some embodiments, when the supporter 61 of the support device 60 is in contact with the substrate 70, the optical probe device 50 will further perform an accurately positioning step for better performance of the optical test in the step d). Specifically speaking, a controller (not shown) may be electrically connected to the distance sensor 52 and a manipulator of the support device 60, and the distance value obtained by the distance sensor 52 is monitored by the controller. When it is observed by the controller that the distance value has a variation, the supporter 61 of the support device 60 is stopped from continuing moving on the vertical axis (Z-axis).
d) Under the status that the supporter 61 of the support device 60 is in contact with the substrate 70, perform an electrical test to the DUT 71 by bringing the electrical probe 41 of the electrical probe device 40 into contact with the DUT 71, and perform an optical test to the DUT 71 by the optical probe device 50.

As schematically illustrated in FIG. 2 and as described, the optical probe device 50 includes a distance sensor 52. The distance sensor 52 is defined with a sensor surface 521 for facing toward a height calibration structure such as the surface of the DUT and/or the optical coupler. For example, the sensor surface 521 is configured to be at least virtually parallel to a surface of the height calibration structure. In such manner, the sensor surface 521 may correspond to and/or be a part of the distance sensor 52, such as a surface of the distance sensor 52 close to the height calibration structure. As described, a position of the distance sensor 52 and/or the sensor surface 521 relative to the height calibration structure may feature in sensing the surface distance. As further schematically illustrated in FIG. 2 and as additionally described, a position of the fiber optical transceiver 51 and/or the optical transceiving surface 511 relative to the height calibration structure and/or the optical coupler may feature in the probing end displacement between the optical transceiving surface 511 and the height calibration structure. For example, the probing end displacement is along a direction at least virtually parallel to the vertical axis. It can be seen from this that the distance sensor 52 of the optical probe device 50 can be utilized to not only determine whether the supporter 61 of the support device 60 is in contact with the substrate 70, but also ensure that the distance between the optical transceiving surface 511 of the optical probe device 50 and the substrate 70 is adapted for the optical test.

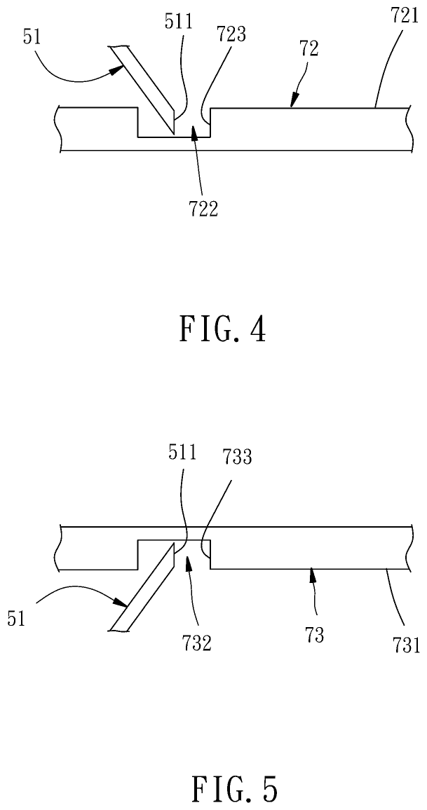

As shown in FIG. 2, the fiber optical transceiver 51 of the optical probe device 50 may extend through a plane, or a surface plane, which may extend within and/or from the sensor surface 521, and the optical transceiving surface 511 of the fiber optical transceiver 51 of the optical probe device 50 may be positioned on a sensor-opposed side of the plane. In other words, in the configuration as shown in FIG. 2 that the fiber optical transceiver 51 extends downwardly toward the substrate 70, the fiber optical transceiver 51 extends beyond the sensor surface 521 and/or the extending surface thereof so that the optical transceiving surface 511 is located lower than the sensor surface 521. Such a configuration may permit and/or facilitate extension of the optical transceiving surface 511 of the fiber optical transceiver 51 of the optical probe device 50 within trench, as shown in FIG. 4 and FIG. 5, prior to, or without, contact, or physical contact, between the sensor surface 521 and the surface of the substrate 70.

Specifically speaking, in the configuration as shown in FIG. 2, the optical receiving portions and optical transmitting portions of the DUT 71 are located on a top surface 721 of the top side 72 of the substrate 70, so the optical transceiving surface 511 of the fiber optical transceiver 51 is configured to face toward the top surface 721 of the substrate 70 to perform the optical test to the DUT 71. However, the optical receiving portions and optical transmitting portions of the DUT 71 may be located on an inner side wall 723 of a recess 722 of the top side 72 of the substrate 70, as shown in FIG. 4, and the optical transceiving surface 511 of the fiber optical transceiver 51 is configured to extend into the recess 722 and face toward the inner side wall 723 of the recess 722 to perform the optical test to the DUT 71.

The distance sensor 52 may include and/or be any suitable sensor that may be adapted, configured, designed, and/or constructed to sense, determine, and/or detect sensed distance. Examples of the distance sensor 52 include a capacitive distance sensor, an optical distance sensor, and/or an interferometer. In general, the distance sensor 52 may be configured to determine the sensed distance to within a threshold distance resolution. Examples of the threshold distance resolution include at most 100 nanometers, at most 50 nanometers, at most 40 nanometers, at most 30 nanometers, at most 20 nanometers, at most 10 nanometers, at most 5 nanometers, at most 4 nanometers, at most 3 nanometers, at most 2 nanometers, at most 1 nanometer, at least 0.1 nanometers, at least 0.5 nanometers, at least 1 nanometer, and/or at least 2 nanometers.

As shown in FIG. 2, the support device 60 in this embodiment further includes a heater 62. The heater 62 may be controlled by a temperature control system (not shown) for heating and cooling. The heater 62 is in thermal communication with the supporter 61, and is configured to control the temperature of the supporter 61 when the DUT 71 is tested by the optical probe device 50 and the electrical probe device 40, so as to heat the substrate 70 through thermal conduction when the supporter 61 is in contact with the substrate 70. Because the heater 62 of the support device 60 uses the contact between the supporter 61 and the substrate 70 to heat the substrate 70 and the supporter 61 can be in contact with the DUT 71 in the testing process or the position adjacent thereto, not only great support effect can be attained, but the DUT 71 in the testing process can be also heated and maintained in temperature efficiently, so that the DUT 71 can be tested under the required high-temperature condition. The heater 62 may be configured to generate heat in any appropriate manner, such as resistive heating by an electric current.

As shown in FIG. 2, the probe system 21 in this embodiment further includes a non-contact heating device 80. The non-contact heating device 80 may be controlled by a temperature control system (not shown) for heating and cooling. The non-contact heating device 80 is configured to heat the substrate 70 through thermal radiation when the DUT 71 is tested by the optical probe device 50 and the electrical probe device 40. As a result, when the above-described heater 62 of the support device 60 heats the DUT 71 through the supporter 61, the non-contact heating device 80 can also heats the DUT 71 at the same time, so that relatively higher heating efficiency is attained. Alternatively, the support device 60 may include no such heater 62, and the DUT 71 is heated by only the non-contact heating device 80, such that the support device 60 is relatively simpler in structure.

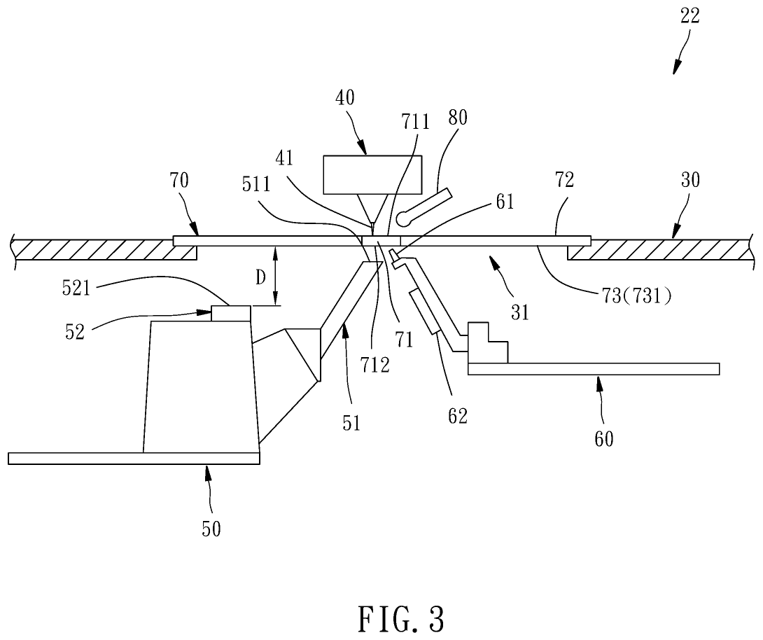

Referring to FIG. 3, a probe system 22 for double side probing according to a second preferred embodiment of the present invention is similar to the above-described probe system 21, but the primary difference therebetween lies in the positional arrangement of the electrical probe device 40, the optical probe device 50 and the support device 60.

In this embodiment, the electrical probe device 40 is the upper probe device, which is disposed above the through hole 31 of the chuck 30 for performing the electrical test to the DUT 71 by contacting the top side 72 of the substrate 70 by the electrical probe 41. The optical probe device 50 is the lower probe device, which is disposed below the through hole 31 of the chuck 30 for performing the optical test to the DUT 71 on the bottom side 73 of the substrate 70. In other words, the DUT 71 in this embodiment is provided on the top side 711 thereof with conductive pads and provided on the bottom side 712 thereof with optical receiving portions and/or optical transmitting portions. Because the electrical probe device 40 is disposed above the through hole 31 of the chuck 30, the support device 60 is disposed below the through hole 31 of the chuck 30. When the DUT 71 is tested by the electrical probe device 40, the electrical probe 41 is in contact with the top side 72 of the substrate 70, and the supporter 61 of the support device 60 is in contact with the bottom side 73 of the substrate 70 and located adjacent to the electrical probe 41 with the substrate 70 located therebetween.

As a result, when the DUT 71 is tested by the probe system 22 in this embodiment, the electrical probe device 40 and the optical probe device 50 can test the DUT 71 on the top side 711 and the bottom side 712 at the same time, thereby attaining the double side probing function. Meanwhile, the electrical probe 41 of the electrical probe device 40 applies a downward force on the top side 72 of the substrate 70, and the supporter 61 of the support device 60 is in contact with the bottom side 73 of the substrate 70 at a position adjacent to where the substrate 70 is applied with the downward force, so as to resist the force from the electrical probe 41, thereby effectively preventing the substrate 70 from deformation. In this way, it can avoid the problem caused by the deformation of the substrate 70 that the optical probe device 50 and the DUT 71 cannot be accurately aligned with each other to result in low accuracy to the test result.

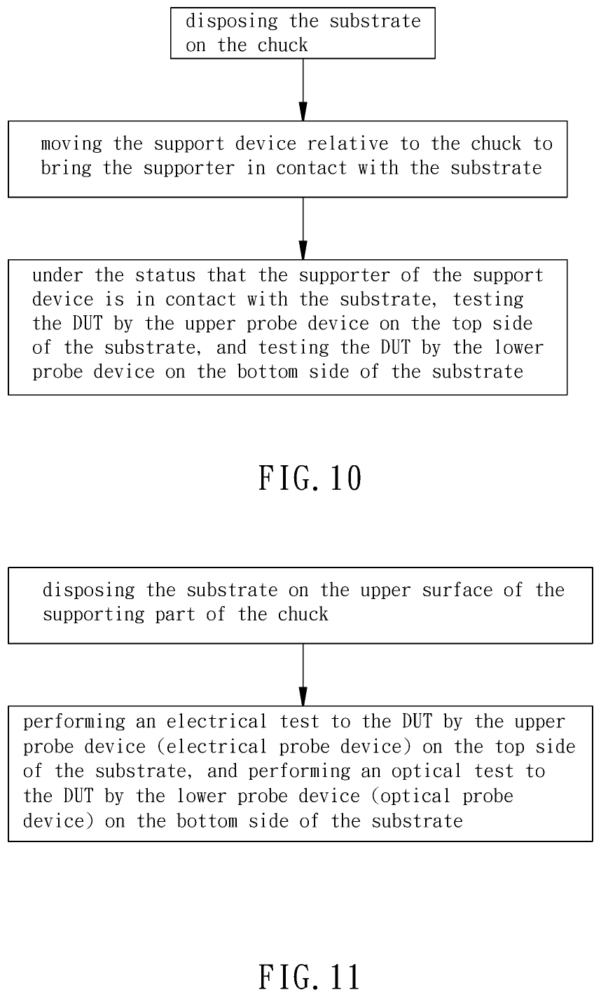

The probe system 22 in this embodiment may also utilize the distance sensor 52 of the optical probe device 50 for the determination of whether the supporter 61 of the support device 60 is in contact with the substrate 70, and the associated method of operating the probe system 22 is similar to the method described in the first preferred embodiment, thereby not repeatedly described hereinafter. However, no matter in the configuration of the first or the second preferred embodiment, it is unlimited to determine whether the supporter 61 of the support device 60 is in contact with the substrate 70 by utilizing the distance sensor 52 of the optical probe device 50. Therefore, the method of operating the probe system of the first and second preferred embodiments may be as shown in FIG. 10. The probe system 22 in this embodiment may also heat the substrate 70 by the heater 62 of the support device 60 and/or the non-contact heating device 80 when the DUT 71 is tested by the upper and lower probe devices, so that the DUT 71 can be tested under the required high-temperature condition.

In the configuration as shown in FIG. 3, the optical receiving portions and optical transmitting portions of the DUT 71 are located on a bottom surface 731 of the bottom side 73 of the substrate 70, so the optical transceiving surface 511 of the fiber optical transceiver 51 is configured to face toward the bottom surface 731 of the substrate 70 to perform the optical test to the DUT 71. However, the optical receiving portions and optical transmitting portions of the DUT 71 may be located on an inner side wall 733 of a recess 732 of the bottom side 73 of the substrate 70, as shown in FIG. 5, and the optical transceiving surface 511 of the fiber optical transceiver 51 is configured to extend into the recess 732 and face toward the inner side wall 733 of the recess 732 to perform the optical test to the DUT 71.

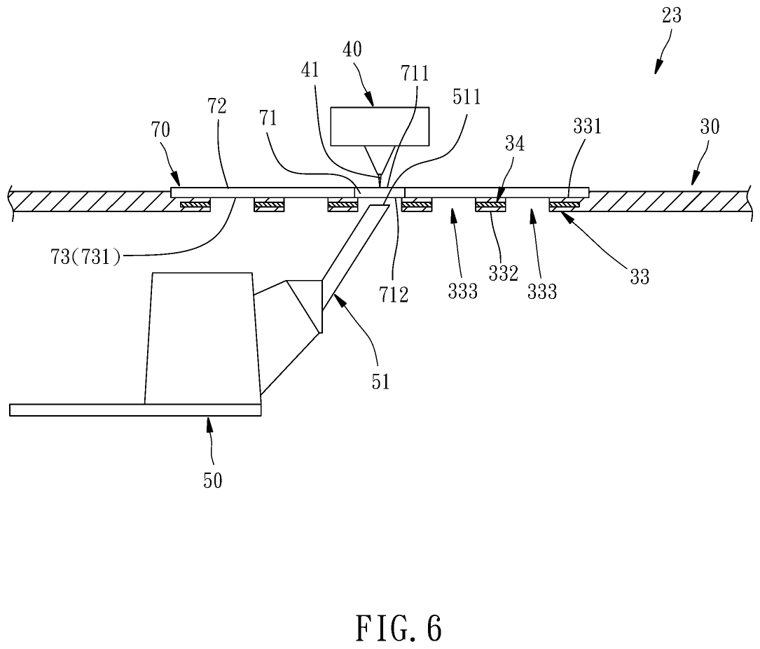

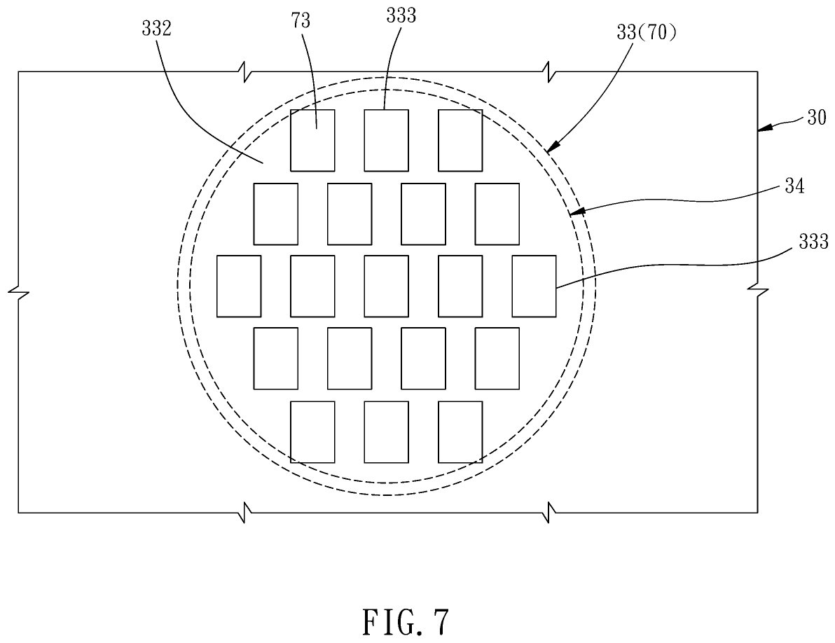

Referring to FIG. 6 and FIG. 7, a probe system 23 for double side probing according to a third preferred embodiment of the present invention is similar to the above-described probe system 22, but the primary difference therebetween lies in that the probe system 23 in this embodiment provides a support mechanism different from the support device 60 disclosed in the first embodiment. That is, the chuck 30 is configured to include a supporting part 33 so that the substrate 70 can be supported by the supporting part 33.

Specifically speaking, the supporting part 33 of the chuck 30 is grid-shaped, which includes an upper surface 331, a lower surface 332, and a plurality of through holes 333 penetrating through the upper surface 331 and the lower surface 332 so that the substrate 70 can be disposed on the upper surface 331 of the supporting part 33 in a way that the substrate 70 is partially located correspondingly to every through hole 333. In this way, the top side 72 of the substrate 70 is completely exposed upwardly, and the bottom side 73 of the substrate 70 is partially exposed downwardly through the through holes 333. In this embodiment, the DUT 71 of the substrate 70 is provided on the top side 711 thereof with conductive pads and provided on the bottom side 712 thereof with optical receiving portions and/or optical transmitting portions. As long as the optical receiving portions and/or optical transmitting portions of the DUT 71 are located at the through holes 333 of the supporting part 33 of the chuck 30, the optical test can be performed to the DUT 71 on the bottom side 73 of the substrate 70 through the through holes 333.

The method of operating the probe system 23 in this embodiment (as shown in FIG. 11) includes disposing the substrate 70 on the upper surface 331 of the supporting part 33 of the chuck 30, and using the upper and lower probe devices to test the DUT 71 on the top side 72 and the bottom side 73 of the substrate 70 respectively. In this embodiment, the electrical probe device 40 is the upper probe device, which is disposed above the supporting part 33 of the chuck 30 for performing the electrical test to the DUT 71 by contacting the top side 72 of the substrate 70 by the electrical probe 41. The optical probe device 50 is the lower probe device, which is disposed below the supporting part 33 of the chuck 30 for performing the optical test to the DUT 71 by making the optical transceiving surface 511 of the fiber optical transceiver 51 face toward the bottom side 73 of the substrate 70 through the through hole 333 of the supporting part 33.

As a result, the probe system 23 in this embodiment can attain the double side probing function, and the supporting part 33 of the chuck 30 supports the bottom side 73 of the substrate 70. When the electrical probe 41 of the electrical probe device 40 applies a downward force on the top side 72 of the substrate 70, the supporting part 33 of the chuck 30 can resist the force from the electrical probe 41, so as to effectively prevent the substrate 70 from deformation. In this way, it can avoid the problem caused by the deformation of the substrate 70 that the optical probe device 50 and the DUT 71 cannot be accurately aligned with each other to result in low accuracy to the test result.

As described in the second preferred embodiment, the optical receiving portions and optical transmitting portions of the DUT 71 may be located on the bottom surface 731 of the substrate 70, and the optical transceiving surface 511 of the fiber optical transceiver 51 is configured to face toward the bottom surface 731 of the substrate 70 to perform the optical test to the DUT 71, as shown in FIG. 6. Alternatively, the optical receiving portions and optical transmitting portions of the DUT 71 may be located on the inner side wall 733 of the recess 732 of the bottom side 73 of the substrate 70, and the optical transceiving surface 511 of the fiber optical transceiver 51 is configured to extend into the recess 732 and face toward the inner side wall 733 of the recess 732 to perform the optical test to the DUT 71, as shown in FIG. 5.

As shown in FIG. 6 and FIG. 7, the chuck 30 in this embodiment further includes a heater 34. The heater 34 may be controlled by a temperature control system (not shown) for heating and cooling, so as to control the temperature of the supporting part 33 of the chuck 30 for heating the substrate 70 through thermal conduction when the supporting part 33 is in contact with the substrate 70. Because the heater 34 of the chuck 30 uses the contact between the supporting part 33 and the substrate 70 to heat the substrate 70 and the supporting part 33 is grid-shaped and thereby can support and heat on the bottom side 73 of the substrate 70 relatively more comprehensively, not only great support effect can be attained, but the DUT 71 in the testing process can be also heated and maintained in temperature efficiently, so that the DUT 71 can be tested under the required high-temperature condition. Besides, the heater 34 may be directly disposed in the supporting part 33 for heating the DUT 71 and maintaining its temperature relatively more efficiently.

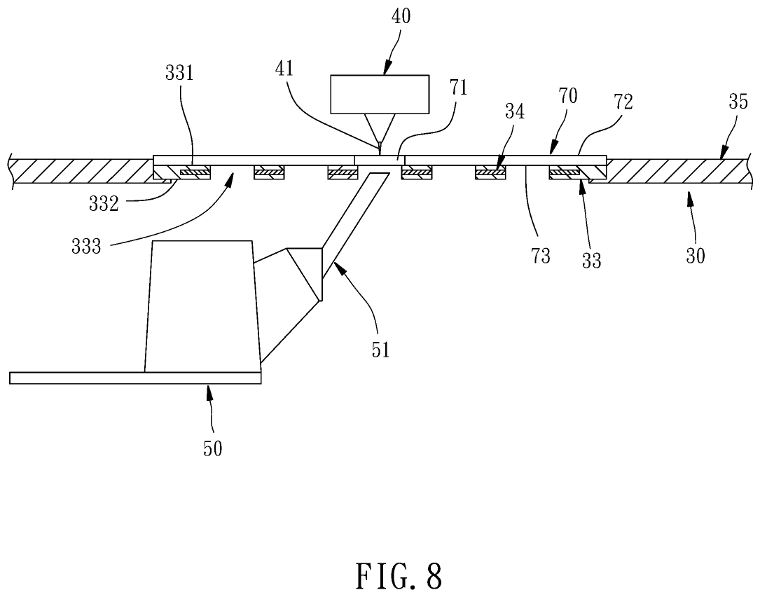

In the configuration as shown in FIG. 6 and FIG. 7, the supporting part 33 of the chuck 30 and other parts of the chuck 30 (except for the heater 34) are formed integrally. However, a modification to the chuck 30 may be made in a way that the chuck is formed as an assembly of structural members, i.e. not an integrally made member as the above-described. For example, as shown in FIG. 8, the chuck 30 includes a main body 35 and a grid plate. The main body 35 and the grid plate are individually manufactured, and then fastened to each other to compose the chuck 30 so that the grid plate becomes the supporting part 33 of the chuck 30.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A probe system for double side probing, which is configured for testing one or more devices under test of a substrate, the probe system comprising:
a chuck configured to support the substrate, the chuck comprising a through hole for the substrate to be disposed on the chuck in a way that the substrate is defined with a central part located correspondingly to the through hole and an edge part located around the central part and supported by the chuck;
an upper probe device disposed above the through hole of the chuck for testing the device under test on a top side of the substrate;
a lower probe device disposed below the through hole of the chuck for testing the device under test on a bottom side of the substrate, the bottom side being opposite to the top side, the bottom side facing toward the chuck; and
a support device comprising a supporter;
wherein one of the upper probe device and the lower probe device is an electrical probe device; the electrical probe device comprises an electrical probe, and the other of the upper probe device and the lower probe device is an optical probe device; the optical probe device comprises a fiber optical transceiver; the optical probe device and the support device are individually movable relative to the chuck; one of the support device and the electrical probe device is disposed above the through hole of the chuck, and the other of the support device and the electrical probe device is disposed below the through hole of the chuck; when the device under test is tested by the electrical probe device, the electrical probe is in contact with one of the top side and the bottom side of the substrate, and the supporter of the support device is in contact with the other of the top side and the bottom side of the substrate and located adjacent to the electrical probe with the substrate located therebetween.

2. The probe system as claimed in claim 1, wherein the lower probe device is the electrical probe device for performing an electrical test to the device under test by contacting the bottom side of the substrate by the electrical probe; the support device is disposed above the through hole of the chuck for contacting the top side of the substrate by the supporter; the upper probe device is the optical probe device for performing an optical test to the device under test on the top side of the substrate.

3. The probe system as claimed in claim 1, wherein the upper probe device is the electrical probe device for performing an electrical test to the device under test by contacting the top side of the substrate by the electrical probe; the support device is disposed below the through hole of the chuck for contacting the bottom side of the substrate by the supporter; the lower probe device is the optical probe device for performing an optical test to the device under test on the bottom side of the substrate.

4. The probe system as claimed in claim 1, wherein the support device further comprises a heater; the heater is configured to control temperature of the supporter when the device under test is tested by the upper probe device and the lower probe device, so as to heat the device under test through thermal conduction when the supporter is in contact with the substrate.

5. The probe system as claimed in claim 1, wherein the probe system further comprises a non-contact heating device; the non-contact heating device is configured to heat the device under test via thermal radiation when the device under test is tested by the upper probe device and the lower probe device.

6. The probe system as claimed in claim 1, wherein when the device under test is tested by the electrical probe device, a distance defined on a horizontal axis between a position where the substrate is contacted by the supporter and another position where the substrate is contacted by the electrical probe is smaller than a length of the device under test defined on the horizontal axis.

7. The probe system as claimed in claim 1, wherein the optical probe device comprises a distance sensor for measuring a distance between the optical probe device and the substrate to generate a distance value for a determination of whether the supporter of the support device is in contact with the substrate by a variation of the distance value.

8. A method of operating the probe system as claimed in claim 7, the method comprising the steps of:
disposing the substrate on the chuck;
moving the optical probe device and the chuck relative to each other to position the optical probe device adjacent to the device under test of the substrate;
using the distance sensor of the optical probe device to measure the distance between the optical probe device and the substrate to generate the distance value, moving the support device relative to the chuck to bring the supporter to be in contact with the substrate, and determining that the supporter of the support device is in contact with the substrate when the distance value obtained by the distance sensor of the optical probe device has a variation; and
under the status that the supporter of the support device is in contact with the substrate, performing an electrical test to the device under test by bringing the electrical probe of the electrical probe device into contact with the device under test, and performing an optical test to the device under test by the optical probe device.

9. A tested device which has been tested through a testing process, the testing process being performed by using the method as claimed in claim 8.

10. A method of operating the probe system as claimed in claim 1, the method comprising:
disposing the substrate on the chuck; and
under the status that the supporter of the support device is in contact with the substrate, testing the device under test by the upper probe device on the top side of the substrate, and testing the device under test by the lower probe device on the bottom side of the substrate;
wherein the upper probe device, the lower probe device and the support device are arranged in one of ways that:
the lower probe device is the electrical probe device and performs an electrical test to the device under test by contacting the bottom side of the substrate by the electrical probe, the support device is disposed above the through hole of the chuck and contacts the top side of the substrate by the supporter, and the upper probe device is the optical probe device and performs an optical test to the device under test on the top side of the substrate; and
the upper probe device is the electrical probe device and performs an electrical test to the device under test by contacting the top side of the substrate by the electrical probe, the support device is disposed below the through hole of the chuck and contacts the bottom side of the substrate by the supporter, and the lower probe device is the optical probe device and performs an optical test to the device under test on the bottom side of the substrate.

11. The method as claimed in claim 10, wherein the fiber optical transceiver of the optical probe device comprises an optical transceiving surface; when performing the optical test to the device under test, the optical probe device is arranged in one of ways that:
the optical transceiving surface of the fiber optical transceiver faces toward a top surface of the top side of the substrate to perform the optical test to the device under test;
the fiber optical transceiver is inserted into a recess of the top side of the substrate, and the optical transceiving surface faces toward an inner side wall of the recess to perform the optical test to the device under test;
the optical transceiving surface of the fiber optical transceiver faces toward a bottom surface of the bottom side of the substrate to perform the optical test to the device under test; and
the fiber optical transceiver is inserted into a recess of the bottom side of the substrate, and the optical transceiving surface faces toward an inner side wall of the recess to perform the optical test to the device under test.

12. A tested device which has been tested through a testing process, the testing process being performed by using the method as claimed in claim 10.

13. A probe system for double side probing, which is configured for testing one or more devices under test of a substrate, the probe system comprising:
a chuck comprising a supporting part which is grid-shaped, the supporting part comprising an upper surface, a lower surface, and a plurality of through holes penetrating through the upper surface and the lower surface for the substrate to be disposed on the upper surface of the supporting part in a way that the substrate is partially located correspondingly to every said through hole;
an electrical probe device disposed above the supporting part of the chuck, the electrical probe device comprising an electrical probe for testing the device under test by contacting a top side of the substrate by the electrical probe; and
an optical probe device disposed below the supporting part of the chuck, the optical probe device comprising a fiber optical transceiver for testing the device under test on a bottom side of the substrate through the through hole of the supporting part.

14. The probe system as claimed in claim 13, wherein the chuck further comprises a heater that heats the substrate through thermal conduction when the supporting part is in contact with the substrate.

15. The probe system as claimed in claim 14, wherein the heater is disposed in the supporting part.

16. A method of operating the probe system as claimed in claim 13, the method comprising:
disposing the substrate on the upper surface of the supporting part of the chuck, testing the device under test by the electrical probe device on the top side of the substrate, and testing the device under test by the optical probe device on the bottom side of the substrate;
wherein the electrical probe device performs an electrical test to the device under test by contacting the top side of the substrate by the electrical probe; the fiber optical transceiver of the optical probe device faces toward the bottom side of the substrate to perform an optical test to the device under test.

17. The method as claimed in claim 16, wherein the fiber optical transceiver of the optical probe device comprises an optical transceiving surface; when performing the optical test to the device under test, the optical probe device is arranged in one of ways that:
the optical transceiving surface of the fiber optical transceiver faces toward a bottom surface of the bottom side of the substrate to perform the optical test to the device under test; and
the fiber optical transceiver is inserted into a recess of the bottom side of the substrate, and the optical transceiving surface faces toward an inner side wall of the recess to perform the optical test to the device under test.

18. A tested device which has been tested through a testing process, the testing process being performed by using the method as claimed in claim 16.
